(19) United States
(12) Patent Application Publication
(10) Pub. No.: US 2009/0166879 A1
(43) Pub. Date: Jul. 2, 2009

(54) SEMICONDUCTOR PACKAGE

(76) Inventors: Kun-Ho Song, Cheonan-si (KR); Yong-Jin Jung, Cheonan-si (KR); Hyun-Ik Hwang, Cheonan-si (KR)

Correspondence Address: STANZIONE & KIM, LLP, 919 18TH STREET, N.W., SUITE 440, WASHINGTON, DC, 20006, US

(21) Appl. No.: 12/343,716

(22) Filed: Dec. 24, 2008

(30) Foreign Application Priority Data
Dec. 26, 2007 (KR) 2007-137031

(51) Int. Cl. H01L 23/528

(52) U.S. Cl. 257/773; 257/E23.151

(57) ABSTRACT

A semiconductor package includes a semiconductor chip, a package substrate, a first attaching member, a second attaching member, a connecting member and a molding member. The package substrate has a central region and an edge region. The first attaching member attaches the semiconductor chip to the central region of the package substrate. The second attaching member is arranged in the edge region of the package substrate. The second attaching member includes first attaching patterns extending in a first direction, and second attaching patterns extending in a second direction. The connecting member electrically connects the semiconductor chip to the package substrate. The molding member is attached to the package substrate using the second attaching member to molding the semiconductor chip.

### CROSS-REFERENCE TO RELATED APPLICATIONS

This application claims priority under 35 USC § 119 to Korean Patent Application No. 2007-137031, filed on Dec. 26, 2007 in the Korean Intellectual Property Office (KIPO), the contents of which are herein incorporated by reference in their entirety.

### BACKGROUND OF THE INVENTION

1. Field of the Invention

The present general inventive concept relates to a semiconductor package and an apparatus having the same. More particularly, the present general inventive concept relates to a semiconductor package including an attaching member to attach the semiconductor to a substrate.

2. Description of the Related Art

Generally, a semiconductor device may be manufactured by a fabricating (FAB) process for forming electrical circuits including electrical elements on a silicon wafer as a semiconductor substrate to form semiconductor chips, an electrical die sorting (EDS) process for testing electrical characteristics of the semiconductor chips , formed by the FAB process, and a packaging process for encapsulating the semiconductor chips and for finalizing the packaged semiconductor as a semiconductor package.

The packaging process may include a process for arranging the semiconductor chip on a die pad of a package substrate as a conductive medium, a process for electrically connecting bonding pads of the semiconductor chip with the package substrate, a process for molding the semiconductor chip with a molding member to protect the semiconductor chip from external impacts, and a process for cutting the semiconductor substrate along a scribe lane to form semiconductor packages.

The semiconductor package may include a semiconductor chip, a package substrate, a first attaching member, a second attaching member and a molding member. The semiconductor chip may have bonding pads. The package substrate may be divided into a central region having a window, and a peripheral region. Further, the package substrate may have bond fingers. The first attaching member may attach the semiconductor chip to the central region of the package substrate. The second attaching member may be arranged in the peripheral region of the package substrate. The molding member may cover the semiconductor chip and the package substrate. The first and second attaching members may be disposed at positions to attach the semiconductor chip to the package substrate.

The bonding pads of the semiconductor chip may be electrically connected to the bond fingers via bonding wires that may pass through the window of the package substrate. Outer terminals such as solder balls may be mounted on a lower surface of the package substrate.

Here, the molding member may be attached to the package substrate using the second attaching member on the peripheral region of the package substrate to mold the package substrate, the semiconductor chip and the bonding wires.

When a large temperature variation may be applied to the semiconductor package during an environmental test, a delamination (delaminating) may be generated between the semiconductor chip and the package substrate due to thermal expansion coefficient difference between the semiconductor chip and the package substrate such that the semiconductor chip and the package substrate are detached or separated, or such that one or more portions between the semiconductor chip and the package substrate are spaced apart from each other. The delamination between the semiconductor chip and the package substrate may cause a deformation to at least one of the semiconductor chip, the package substrate, and the molding. The delamination may cause generations of shearing stresses. The shearing stress may be transmitted to the molding to create cracks on the molding or a portion between the molding and the package substrate. The shearing stresses may also be transmitted to the solder halls, so that cracks or delamination may be generated in the solder balls.

### SUMMARY OF THE INVENTION

The present general inventive concept provides a semiconductor package that may be capable of suppressing a delamination between a semiconductor chip and, a package substrate.

The present general inventive concept also provides a semiconductor package with an improved attaching member.

Additional aspects and utilities of the present general inventive concept will be set forth in part in the description which follows and, in part, will be obvious from the description, or may be learned by practice of the general inventive concept.

In an embodiment and utilities of the present general inventive concept, there is provided a semiconductor package. The semiconductor package may include a semiconductor chip, a package substrate, a first attaching member, a second attaching member, a connecting member and a molding member. The package substrate may have a central region and an edge region. The first attaching member may attach the semiconductor chip to the central region of the package substrate. The second attaching member may be arranged in the edge region of the package substrate. The second attaching member may include first attaching patterns extending in a first direction, and second attaching patterns extending in a second direction. The connecting member may electrically connect the semiconductor chip to the package substrate. The molding member may be attached to the package substrate using the second attaching member to molding the semiconductor chip.

The first direction may be substantially the same as the second direction.

The first direction may be substantially perpendicular to the second direction.

The first attaching patterns and the attaching second patterns may be intersected with each other at corners of the package substrate.

The first attaching patterns and the second attaching patterns may have a bar shape.

The first attaching patterns and the second attaching patterns may be inclined to a side surface of the package substrate.

The first attaching patterns and the second attaching patterns may have a wavelike shape.

The extending directions of the first attaching patterns and the second attaching patterns may be substantially the same as arrangement directions of the first attaching patterns and the second attaching patterns.

The extending directions of the first attaching patterns and the second attaching patterns may be substantially perpendicular to the arrangement directions of the first attaching patterns and the second attaching patterns.

The semiconductor package may further include outer terminals electrically connected to the semiconductor chip and the package substrate.

In an embodiment and utilities of the present general inventive concept, there is also provided a semiconductor package. The semiconductor package may include a semiconductor chip, a package substrate, a first attaching member, a second attaching member, a bonding wire and a molding member. The package substrate may have a central region and an edge region. The first attaching member may attach the semiconductor chip to the central region of the package substrate. The second attaching member may be arranged in the edge region of the package substrate. The second attaching member may include attaching patterns spaced apart from each other by substantially the same interval. The bonding wire may electrically connect the semiconductor chip to the package substrate. The molding member may be attached to the package substrate using the second attaching member to molding the semiconductor clip.

The attaching patterns may have a bar shape extending a straight direction. The extending directions of the attaching patterns may be substantially the same as an arrangement direction of the attaching patterns.

The attaching patterns may have a bar shape extending a straight direction. The extending directions of the attaching patterns may be substantially perpendicular to the arrangement direction of the attaching patterns.

The attaching patterns may have a wavelike shape.

The attaching patterns may include first attaching patterns extending in a first direction, and a second attaching patterns extending in a second direction substantially perpendicular to the first direction.

The second attaching member to attaché the molding member to the package substrate may include the repetitive patterns. Further, the patterns may be spaced apart from each other by substantially the same interval. Therefore, a delamination between the molding member and the package substrate may be effectively suppressed.

In an embodiment and utilities of the present general inventive concept, there is also provided a semiconductor package including a package substrate, a semiconductor disposed on the package substrate, a molding formed on the package and the semiconductor, and an attaching member disposed between the package substrate and the molding, and having at least two different patterns.

The at least two different patterns of the attaching member may be disposed on at least two different portions between the package substrate and the molding.

The at least two different patterns of the attaching member may be disposed on at least two different portions between the semiconductor and outer peripheral sides of the package substrate.

The at least two different patterns of the attaching member may include a plurality of bars having corresponding spaces therebetween by a distance.

The molding may be disposed in the spaces.

The at least two different patterns of the attaching member may include spaces, and the molding is filled in the spaces.

The semiconductor may include at least two sides to contact the molding, and the at least two different patterns of the attaching member are disposed along the corresponding sides of the semiconductor chip.

Each of the at least two different patterns of the attaching member may include one or more bar-shape elements spaced apart from each other to be parallel to a direction of a side of the semiconductor chip.

Each of the at least two different patterns of the attaching member may include one or more bar-shape elements spaced apart from each other to be parallel to a direction of a side of the package substrate.

The semiconductor may include at least two sides in different direction to contact the molding, and each of the at least two different patterns of the attaching member comprise a length in the direction, a thickness in a direction perpendicular to the direction, and a height in another direction perpendicular to the directions.

The length may be longer than the thickness and the height.

Each of the at least two different patterns of the attaching member may include one or more bar-shape elements spaced apart from each other to be parallel to a direction of a side of the semiconductor chip.

The length may be longer than the thickness.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a cross-sectional view illustrating a semiconductor package according to an embodiment of the present general inventive concept;

FIG. 2 is a cross-sectional view illustrating a second attaching member of the semiconductor package in FIG. 1;

FIG. 3 is a cross-sectional view illustrating a second attaching member of a semiconductor package according to an embodiment of the present general inventive concept;

FIG. 4 is a cross-sectional view illustrating a second attaching member of a semiconductor package according to an embodiment of the present general inventive concept;

FIG. 5 is a cross-sectional view illustrating a second attaching member of a semiconductor package according to an embodiment of the present general inventive concept;

FIG. 6 is a cross-sectional view illustrating a second attaching member of a semiconductor package according to an embodiment of the present general inventive concept;

FIG. 7 is a cross-sectional view illustrating a second attaching member of a semiconductor package according to an embodiment of the present general inventive concept;

FIGS. 8 to 12 are cross-sectional views illustrating a method of manufacturing a semiconductor package according to an embodiment of the present general inventive concept; and

FIG. 13 is a view illustrating an apparatus having a semiconductor package and a processing unit to process data of the semiconductor package according to an embodiment of the present general inventive concept.

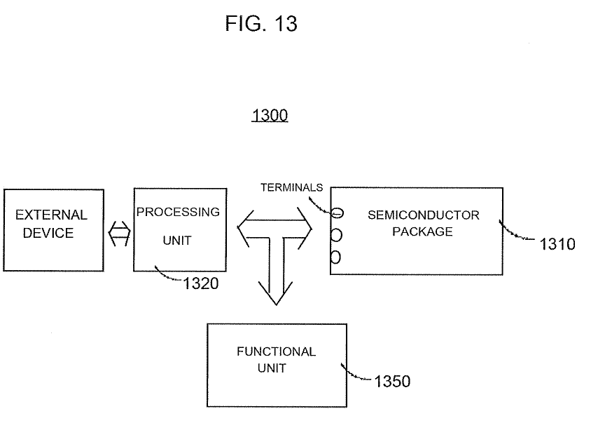

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present general inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present general inventive concept.

Unless otherwise defined, all terms (including technical and scientific terms) used herein have the same meaning as commonly understood by one of ordinary skill in the art to which this present general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

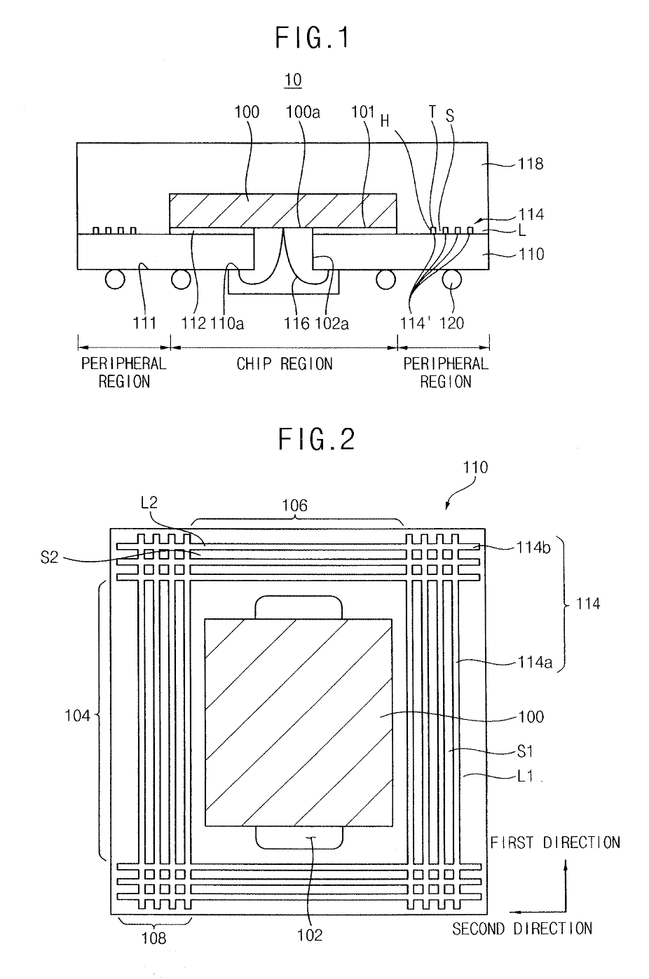

FIG. 1 is a cross-sectional view illustrating a semiconductor according to an embodiment of the present general inventive concept.

Referring to FIG. 1, a semiconductor package 10 of this example embodiment may include a semiconductor chip 100, a package substrate 110, a first attaching member 112, a second attaching member 114, a connecting member 116, a molding member 118 and outer terminals 120. The package substrate 110 may have a chip region and a peripheral region. Here, the semiconductor chip 110 may be located in the chip region of the package substrate 110. In this example embodiment, the chip region of the package substrate 110 may correspond to a central region of the package substrate 110. The peripheral region of the package substrate 110 may correspond to an edge region of the package substrate 110. The first attaching member 112 may be arranged in the chip region of the package substrate 110. The second attaching member 114 may be arranged in the peripheral region of the package substrate 110.

The semiconductor chip 110 can be attached to the package substrate 110 according to an attaching force of at least one of the first attaching member 112 and the second attaching member 114. It is possible that when the molding member 118 is formed on the package substrate 110, the attaching force can be applied to the package substrate 110.

The semiconductor chip 100 may include one or more first bonding pads 100a. The first bonding pads may be arranged on an active surface 101 of the semiconductor chip 100. In this case, the active surface 101 of the semiconductor chip 10 faces the package substrate 110.

In this example embodiment, the semiconductor chip 100 may have a center pad type where the first bonding pads 100a may be arranged on a central portion of the active surface 101 of the semiconductor chip 100. Alternatively, the semiconductor chip 100 may have an edge pad type where the first bonding pads 100a may be arranged on a peripheral portion of the active surface of the semiconductor chip 100.

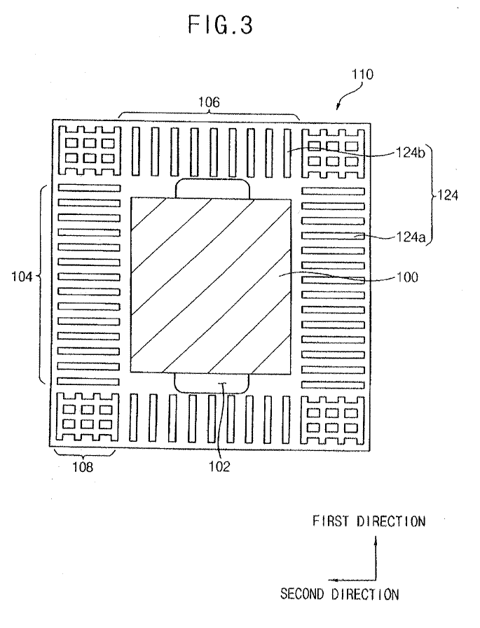

The package substrate 110 may extend in a first direction. In this example embodiment, the package substrate 110 may have a rectangular shape. The package substrate 110 has longitudinal sides which are parallel to the first direction. As mentioned above, the package substrate 110 may have the chip region and the peripheral region. The semiconductor chip 100 may be mounted on the chip region of the package substrate 110. The chip region of the package substrate 110 may have a size substantially the same as that of the semiconductor chip 100. Further, a window 102 (See FIG. 2) may be defined by inside walls of the package substrate 110 and/or formed in the chip region of the package substrate 110. The window 102 may have a shape having longitudinal sides to extend in the first direction.

The package substrate 110 may have second bonding pads 110a. The second bonding pads may be arranged on an active surface 111 of the package substrate 110.

The active surfaces 101 and 111 may be a surface having a terminal or conductive line to be connected to an external circuit or terminal of an external device. Here, the pads 100a and 110a are disposed on the active surfaces 101 and 111, respectively.

In this example embodiment, when the semiconductor chip 100 may have the center pad type, the active surfaces 101 and 111 of the semiconductor chip 100 and the package substrate 110 may be arranged oriented toward a downward direction. Thus, the first bonding pads 100a may be exposed through the window 102 of the package substrate 110.

Alternatively, when the semiconductor chip 100 may have the edge pad type, the active surfaces of the semiconductor chip 100 and the package substrate 110 may be arranged oriented toward an upward direction. In this case, the package substrate 110 may not have the window 102.

In this example embodiment, examples of the package substrate 110 may include a printed circuit substrate, a tape wire substrate, a ceramic substrate, etc.

Although FIG. 1 illustrates the active surfaces 101 and 111 disposed to face the same direction, it is possible that the active surfaces can be disposed to face each other. In this case, the pads of the active surfaces are connected when the active surfaces are disposed to face each other. Since the outer terminals 120 are formed on a surface opposite to the active surface, a surface having the outer terminals 120 may be disposed to face an outside of the semiconductor package 10 such that the outer terminals 120 can be connected to an external device to transmit or receive data to be stored in a memory unit of the semiconductor chip 100. Also, the outer terminals 120 may be connected to the pads of active surface of the package substrate 110 through a body of the package substrate 110.

The connecting member 116 may electrically connect the first bonding pads of the semiconductor chip 100 with the second bonding pads of the package substrate 110. In this example embodiment, the connecting member 116 may be electrically connected between the first bonding pads of the semiconductor chip 100 and the second bonding pads of the package substrate 110 through the window 102.

In this example embodiment, the connecting member 116 may be a bonding wire including a conductive material, such as a metal. For example, the bonding wire 116 may include gold, silver, platinum, nickel, copper, aluminum, etc.

The first attaching member 112 may be arranged in the chip region of the package substrate 110. The first attaching member 112 may attach the semiconductor chip 100 to the package substrate 110. In this example embodiment, the first attaching member 112 may be entirely positioned on the chip region of the package substrate 110 except for the window 102. Alternatively, the first attaching member 112 may be partially positioned on the chip region of the package substrate 110 except for the window 102.

In this example embodiment, the first attaching member 112 may include silicon, silver epoxy, a liquid adhesive, an adhesive film, etc.

The second attaching member 114 may be arranged in the peripheral region of the package substrate 110. The second attaching member 114 may attach the molding member 118 to the package substrate 110.

The second attaching member 114 may include first attaching patterns extending in the first direction, and second attaching patterns extending in a second direction. Further, the first attaching patterns and the second attaching patterns may be alternately arranged spaced apart from each other by substantially the same interval. In this example embodiment, the first direction may be substantially the same as the second direction. Alternatively, the first direction may be different from the second direction. For example, the first direction may be substantially perpendicular to the second direction.

In this example embodiment, the second attaching member 114 may include silicon, silver epoxy, a liquid adhesive, an adhesive film, etc. For example, the second attaching member 114 may include a material substantially the same as that of the first attaching member 112.

Here, as mentioned above, the second attaching member 114 may include the first attaching patterns and the second attaching patterns alternately arranged spaced apart from each other by substantially the same interval. Therefore, a contact area between the second attaching member 114 and the molding member 118 may be enlarged, so that the molding member 118 may not be delaminated from the package substrate 110.

Here, detail structures of the second attaching member 114 of some example embodiments may be illustrated with reference to following drawings.

The molding member 118 may surround the connecting member 116, the semiconductor chip 100 and the package substrate 110 to fill up the window 102. The molding member 118 may protect the connecting member 116, the semiconductor chip 100 and the package substrate 110 from external environments such as impacts.

In this example embodiment, the molding, member 118 may have a liquid type or a tape type. For example, the molding member 118 may include a liquid molding material, a molding compound, etc. Particularly, the molding compound may include epoxy, polyimide, polybenzoxazole, benzocyclobutene, etc.

The outer terminals 120 may be mounted on a lower surface of the package substrate 110. The outer terminals 120 may be electrically connected with the semiconductor chip 100. In this example embodiment, examples of the outer terminals 120 may include a solder ball, a solder bump, a metal bump, etc. Further, the metal bump may include copper, gold, nickel, etc.

The second attachment member may include a plurality of attachment elements 114′. The attachment elements 114′ may be spaced apart from each other to form a space therebetween. The number of attachment elements 114′ may be different from each other according to locations of the molding member 118 or the package substrate 110. The attachment elements 114′ may have different shapes depending on locations of the molding member 118 or the package substrate 110. The shape may have a height H, a thickness T, and a length L. The height H, thickness T, and length L of each attachment elements 114′ may be different from one another within the same location. It is also possible that the height H, thickness T, and length L may be different from one another according to the locations of the molding member 118 or the package substrate 110.

FIG. 2 is a cross-sectional view illustrating the second attaching member 114 of the semiconductor package in FIG. 1.

Referring to FIG. 2, the second attaching member 114 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The second attaching member 114 may include first attaching patterns 114a and second attaching patterns 114b. The first attaching patterns 114a may be arranged in the first region 104 of the package substrate 110. In this example embodiment, the first attaching patterns 114a may have a bar shape extending in the first direction. The second attaching patterns 114b may be arranged in the second region 106 of the package substrate 110. In this example embodiment, the second attaching patterns 114b may have a bar shape extending in the second direction. The first attaching patterns 114a and the second attaching patterns 114b may extend into the third region 108 of the package substrate 110. Thus, the first attaching patterns 114a and the second attaching patterns 114b may be intersected with each other in the third region 108.

In this example embodiment, the first attaching patterns 114a may be arranged in parallel with each other. The second attaching patterns 114b may be arranged in parallel with each other. Further, the first attaching patterns 114a may be spaced apart from each other by substantially the same interval. The second attaching patterns 114b may be spaced apart from each other by substantially the same interval. Here, the intervals between the first attaching patterns 114a and between the second attaching patterns 114b may allow the molding member 118 to fill up spaces between the first attaching patterns 114a and between the second attaching patterns 114b.

The first patterns 114a and second patterns 114b may have a plurality of attachment elements 114′ as described above with respect to FIG. 1. The length L of the attachment elements 114′ of the first patterns 114a may be a first length L1, and the length L of the attachment elements 114′ of the second patterns 114b may be a second length L2. The space S of the attachment elements 114′ of the first patterns 114a may be a first space S1, and the space S of the attachment elements 114′ of the second patterns 114b may be a second space S2.

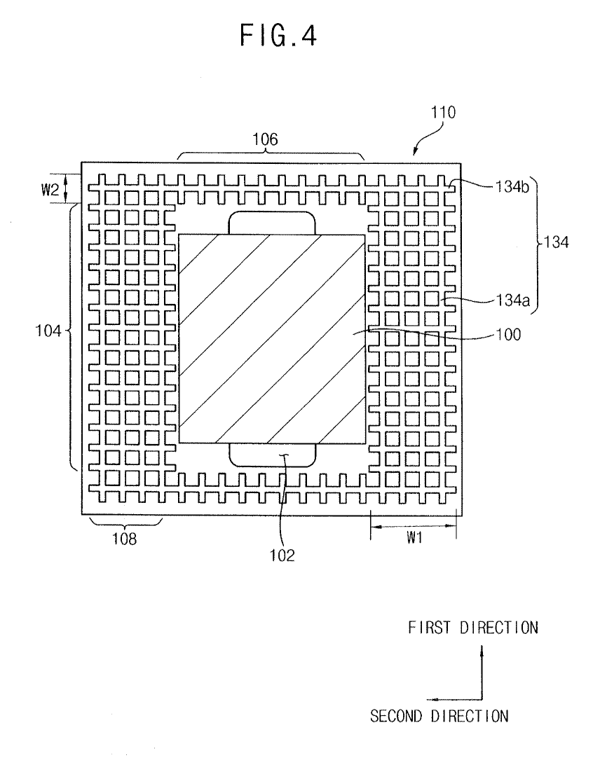

FIG. 3 is a cross-sectional view illustrating a second attaching member of a semiconductor package according to an embodiment of the present general inventive concept.

Referring to FIG. 3, the second attaching member 124 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The second attaching member 124 may include first attaching patterns 124a and second attaching patterns 124b. The first attaching patterns 124a may be arranged in the first region 104 of the package substrate 110. In this example embodiment, the first attaching patterns 124a may have a bar shape extending in the second direction. The second attaching patterns 124b may be arranged in the second region 106 of the package substrate 110. In this example embodiment, the second attaching patterns 124b may have a bar shape extending in the first direction. The first attaching patterns 124a and the second attaching patterns 124b may extend into the third region 108 of the package substrate 110. Thus, the first attaching patterns 124a and the second attaching patterns 124b may be intersected with each other in the third region 108. The third region 108 may be spaced apart from at least one of the first region 104 and the second region 106.

In this example embodiment, the first attaching patterns 124a may be arranged in parallel with each other. The second attaching patterns 124b may be arranged in parallel with each other. Further, the first attaching patterns 124a may be spaced apart from each other by substantially the same interval. The second attaching patterns 124b may be spaced apart from each other by substantially the same interval. Here, the intervals between the first attaching patterns 124a and between the second attaching patterns 124b may allow the molding member 118 to fill up spaces between the first attaching patterns 124a and between the second attaching patterns 124b.

The first patterns 124a and second patterns 124b may have a plurality of attachment elements having a height H, a thickness T, and a length L according to locations with respect to the semiconductor chip 100, as described above with respect to FIG. 1. It is possible that dimensions or shapes of the attachment elements of the second attaching member 124 are different from each other. However, the present general inventive concept is not limited thereto. It is also possible that at least one of the dimensions or shapes of the attachment elements of the second attaching member 124 is same. The molding member 118 may be filled between the attachment elements.

The first region 104 may be larger than the second region 106 or the third region 108. However, the present general inventive concept is not limited thereto. It is also possible that the third region is smaller than the first region and the second region.

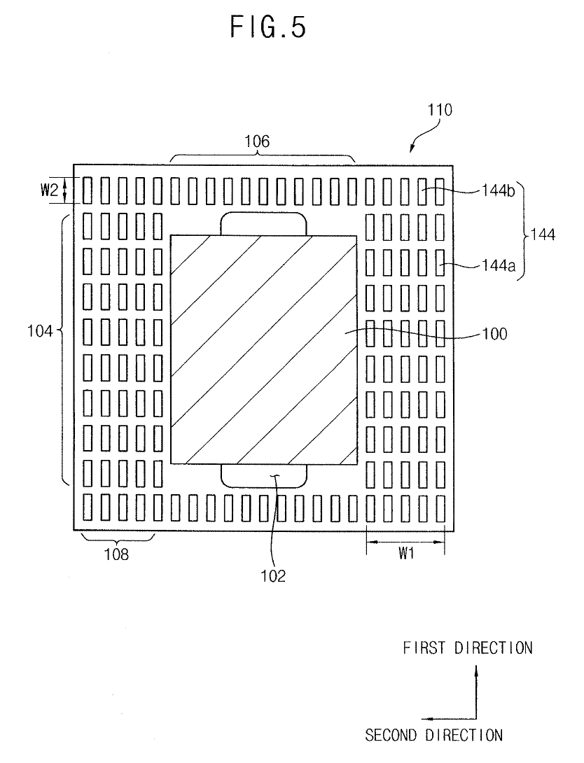

FIG. 4 is a cross-sectional view illustrating a second attaching member of a semiconductor package according to an embodiment of the present general inventive concept.

Referring to FIG. 4, the second attaching member 134 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The first region 104 may have a width W1, and the second region 106 may have a width W2 narrower than the width W1 of the first region. The third region 108 may have the width W1 and the width W2 as sides thereof, and is disposed between the first region 104 and the second region 108. The first region 104, the second region 106 and the third region 108 may be disposed to be connected to one another.

The second attaching member 134 may include first attaching patterns 134a and second attaching patterns 134b. In this example embodiment, the first attaching patterns 134a may have a bar shape extending in the first direction. The second attaching patterns 134b may have a bar shape extending in the second direction. The first attaching patterns 134a and the second attaching patterns 134b may be arranged in the first region 104, the second region 106 and the third region 108 of the package substrate 110. Thus, the second attaching member may have a structure where the first attaching patterns 134a and the second attaching patterns 134b may be intersected with each other. That is, the second attaching member of this example embodiment may have a meshed structure.

In this example embodiment, the first attaching patterns 134a may be arranged in parallel with each other. The second attaching patterns 134b may be arranged in parallel with each other. Further, the first attaching patterns 134a may be spaced apart from each other by substantially the same interval. The second attaching patterns 134b may be spaced apart from each other by substantially the same interval. Particularly, the first attaching patterns 134a and the second attaching patterns 134b may be spaced apart from each other by substantially the same interval. Here, the intervals between the first attaching patterns 134a and the second attaching patterns 134b may allow the molding member 118 to fill up spaces between the first attaching patterns 134a and the second attaching patterns 134b.

The first patterns 134a and second patterns 134b may have a plurality of attachment elements having a height H, a thickness T, and a length L according to locations with respect to the semiconductor chip 100, as described above. It is possible that dimensions or shapes of the attachment elements of the second attaching member 134 are different from each other. However, the present general inventive concept is not limited thereto. It is also possible that at least one of the dimensions or shapes of the attachment elements of the second attaching member 134 is same. The attachment elements of the second attaching member 134 may be not disconnected but connected to one another. The molding member 118 may be filled between the attachment elements.

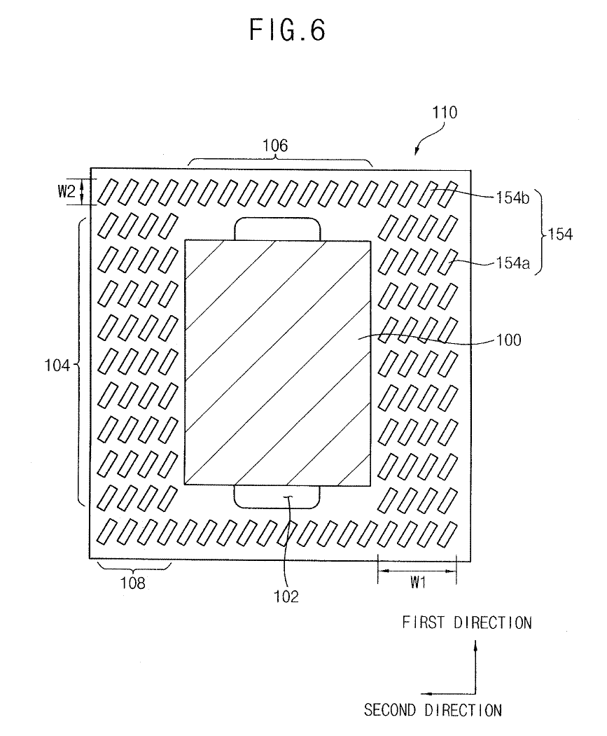

FIG. 5 is a cross-sectional view illustrating a second attaching member of a semiconductor package according to an embodiment of the present general inventive concept.

Referring to FIG. 5, the second attaching member 144 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The first region 104 may have a width W1, and the second region 106 may have a width W2 narrower than the width W1 of the first region. The third region 108 may have the width W1 and the width W2 as sides thereof, and is disposed between the first region 104 and the second region 108.

The second attaching member 144 may include first attaching patterns 144a and second attaching patterns 144b. The first attaching patterns 144a may be arranged in the first region 104 of the package substrate 110. In this example embodiment, the first attaching patterns 144a may have a bar shape extending in the first direction. The second attaching patterns 144b may be arranged in the second region 106 of the package substrate 110. In this example embodiment, the second attaching patterns 144b may have a bar shape extending in the first direction.

In this example embodiment, the first attaching patterns 144a may be arranged in parallel with each other. The second attaching patterns 144b may be arranged in parallel with each other. The first attaching patterns 144a and the second attaching patterns 144b may be arranged in parallel with each other. Further, the first attaching patterns 144a may be spaced apart from each other by substantially the same interval. The second attaching patterns 144b may be spaced apart from each other by substantially the same interval. The interval between the first attaching patterns 144a may be substantially the same as that between the second attaching patterns 144b.

The first patterns 144a and second patterns 144b may have a plurality of attachment elements having a height H, a thickness T, and a length L according to locations with respect to the semiconductor chip 100, as described above. It is possible that dimensions or shapes of the attachment elements of the second attaching member 144 are different from each other. However, the present general inventive concept is not limited thereto. It is also possible that at least one of the dimensions or shapes of the attachment elements of the second attaching member 144 is same. The attachment elements of the second attachment member 144 may not be connected but disposed to be spaced apart one another. The attachment elements of the second attachment member 144 may have the same dimension and shape. The molding member 118 may be filled between the attachment elements.

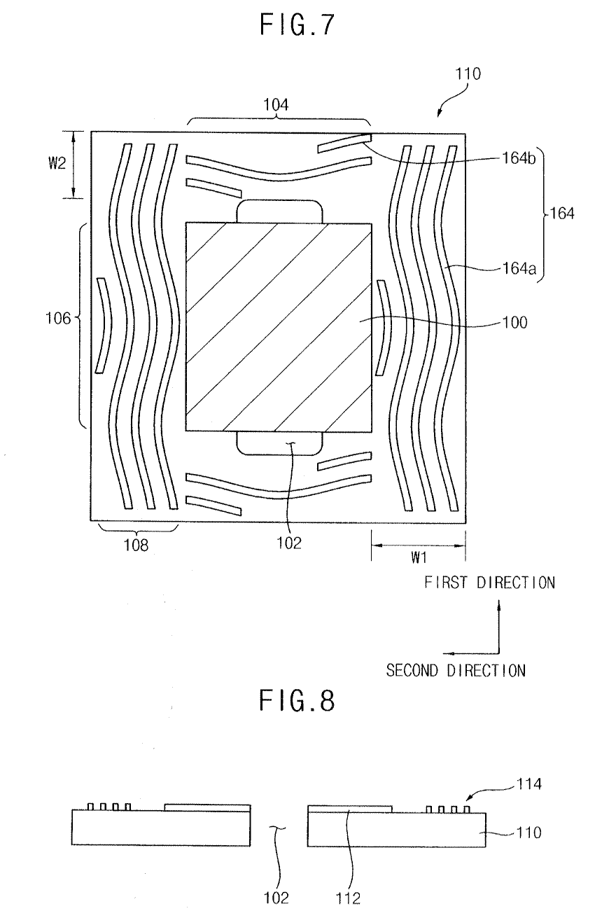

FIG. 6 is a cross-sectional view illustrating a second attaching member of a semiconductor package according to an embodiment of the present general inventive concept.

Referring to FIG. 6, the second attaching member 154 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The first region 104 may have a width W1, and the second region 106 may have a width W2 narrower than the width W1 of the first region. The third region 108 may have the width W1 and the width W2 as sides thereof, and is disposed between the first region 104 and the second region 108.

The second attaching member 154 may include first attaching patterns 154a and second attaching patterns 154b. The first attaching patterns 154a may be arranged in the first region 104 of the package substrate 110. In this example embodiment, the first attaching patterns 154a may have a bar shape inclined to the first direction. The second attaching patterns 154b may be arranged in the second region 106 of the package substrate 110. In this example embodiment, the second attaching patterns 154b may have a bar shape inclined to in the first direction. In this example embodiment, the inclined angle of the first attaching patterns 154a may be substantially the same as that of the second attaching patterns 154b.

In this example embodiment, the first attaching patterns 154a may be arranged in parallel with each other. The second attaching patterns 154b may be arranged in parallel with each other. The first attaching patterns 154a and the second attaching patterns 154b may be arranged in parallel with each other. Further, the first attaching patterns 154a may be spaced apart from each other by substantially the same interval. The second attaching patterns 154b may be spaced apart from each other by substantially the same interval. The interval between the first attaching patterns 154a may be substantially the same as that between the second attaching patterns 154b.

The first patterns 154a and second patterns 154b may have a plurality of attachment elements having a height H, a thickness T, and a length L according to locations with respect to the semiconductor chip 100, as described above. It is possible that dimensions or shapes of the attachment elements of the second attaching member 154 are different from each other. However, the present general inventive concept is not limited thereto. It is also possible that at least one of the dimensions or shapes of the attachment elements of the second attaching member 154 is same. The attachment elements of the second attachment member 154 may not be connected but disposed to be spaced apart one another. The attachment elements of the second attachment member 154 may have the same dimension and shape. The molding member 118 may be filled between the attachment elements.

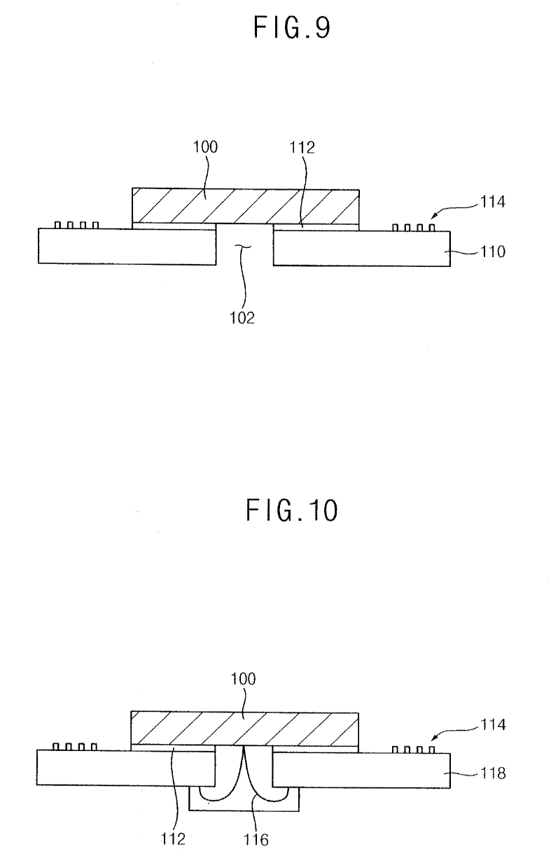

FIG. 7 is a cross-sectional view illustrating a second attaching member of a semiconductor package according to an embodiment of the present general inventive concept.

Referring to FIG. 7, the second attaching member 164 may be arranged in the peripheral region of the package substrate 110. Here, the peripheral region of the package substrate 110 may be divided into a first region 104 extending in the first direction, a second region 106 extending in the second direction substantially perpendicular to the first direction, and a third region 108 with which the first region 104 and the second region 106 may be intersected.

The first region 104 may have a width W1, and the second region 106 may have a width W2 narrower than the width W1 of the first region. The third region 108 may have the width W1 and the width W2 as sides thereof, and is disposed between the first region 104 and the second region 108.

The second attaching member 164 may include first attaching patterns 164a and second attaching patterns 164b. The first attaching patterns 164a may be arranged in the first region 104 of the package substrate 110. Further, the first attaching patterns 164a may extend into the third region 108. In this example embodiment, the first attaching patterns 164a may have a wavelike extending in the first direction. The second attaching patterns 164b may be arranged in the second region 106 of the package substrate 110. In this example embodiment, the second attaching patterns 164b may have a wavelike shape extending in the second direction.

In this example embodiment, the first attaching patterns 164a may be arranged in parallel with each other. The second attaching patterns 164b may be arranged in parallel with each other. Further, the first attaching patterns 164a may be spaced apart from each other by substantially the same interval. The second attaching patterns 164b may be spaced apart from each other by substantially the same interval. The interval between the first attaching patterns 164a may be substantially the same as that between the second attaching patterns 164b.

The first patterns 164a and second patterns 164b may have a plurality of attachment elements having a height H, a thickness T, and a length L according to locations with respect to the semiconductor chip 100, as described above. It is possible that dimensions or shapes of the attachment elements of the second attaching member 164 are different from each other. However, the present general inventive concept is not limited thereto. It is also possible that at least one of the dimensions or shapes of the attachment elements of the second attaching member 164 is same. The attachment elements of the second attachment member 164 may be disposed on a line which is not parallel to the first direction and the second direction. The line may be a curved line with respect to the first direction and the second direction. The attachment elements of the second attachment member 164 may have different lengths in a direction of the first direction and/or the second direction. The attachment elements of the second attachment member 164 may have different lengths within corresponding ones of the first region 104, the second region 106, and the third region 108. The molding member 118 may be filled between the attachment elements.

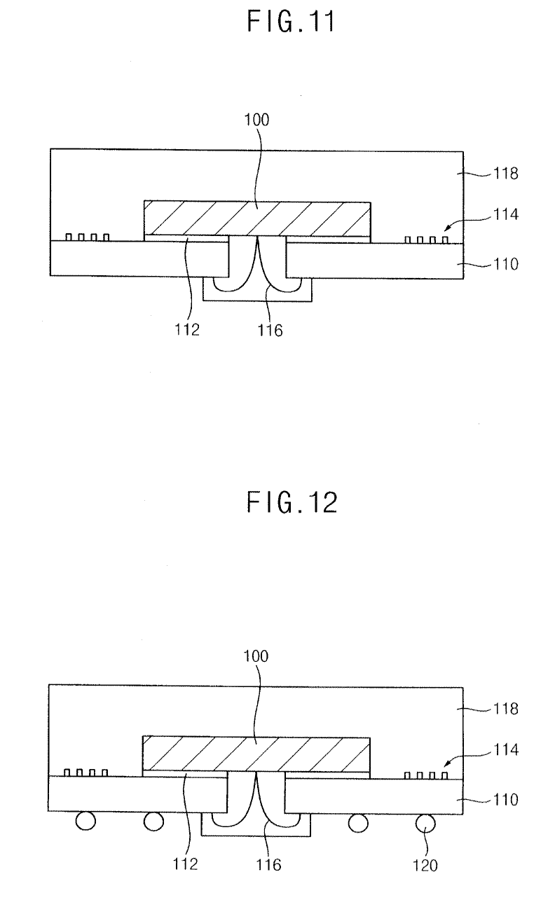

FIGS. 8 to 12 are cross-sectional views illustrating a method of manufacturing a semiconductor package according to an embodiment of the present general inventive concept.

Referring to FIG. 8, a package substrate 110 may be prepared. In this example embodiment, the package substrate 110 may have a chip region and a peripheral region. A window 102 may be formed in the chip region. Further, the package substrate 110 may include first bonding pads (100a of FIG. 1). The first bonding pads may be arranged in an active surface of the package substrate 110. The active surface of the package substrate 110 may be arranged oriented toward a downward direction.

A mask (not illustrated) may then be formed on the package substrate 110. In this example embodiment, the mask may expose regions of the package substrate 110 where a first attaching member 112 and a second attaching member 114 may be to be formed, and mask the rest of regions of the package substrate 110 except for the regions in which the first attaching member 112 and the second attaching member 114 may be to be formed. The first attaching member 112 may be formed on the chip region of the package substrate 110 except for the window 102. Further, the second attaching member 114 may be formed on the peripheral region of the package substrate 110. As illustrated in FIG. 2, the second attaching member 114 may include first attaching patterns extending in a first direction, and second attaching patterns extending in a second direction substantially perpendicular to the first direction. However, the second attaching member 114 may not be restricted within the above-mentioned structure. For example, the second attaching member 114 may include attaching patterns alternately spaced apart from each other by substantially the same interval to enlarge a contact area between a molding member 118 and the second attaching member 114.

An adhesive (not illustrated) may then be coated on the mask. The adhesive may be selectively positioned on exposed regions of the package substrate 110 through the mask. In this example embodiment, the adhesive may include silicon, silver epoxy, a liquid adhesive, etc.

Referring to FIG. 9, a semiconductor chip 100 may be placed on the package substrate 110 having the adhesive. In this example embodiment, the semiconductor chip 100 may have a center pad type. Thus, second bonding pads may be arranged on a central portion of an active surface of the semiconductor chip 100.

The active surface of the semiconductor chip 100 may be arranged oriented toward the downward direction. Thus, the bonding pads of the semiconductor chip 100 may be exposed through the window 102.

A heat and a pressure may be applied to the semiconductor chip 100 to attach the semiconductor chip 100 to the package substrate 110. As a result, the first attaching member 112 may be formed between the semiconductor chip 100 and the package substrate 110.

Referring to FIG. 10, the package substrate 110 and the semiconductor chip 100 may be electrically connected with each other using a connecting member 116. In this example embodiment, the first bonding pads of the package substrate 110 may be electrically connected to the second bonding pads of the semiconductor chip 100 using the connecting member 116 that may pass through the window 102.

In this example embodiment, the connecting member 116 may include a bonding wire including a metal. For example, the connecting member 116 may include gold, silver, platinum, nickel, copper, aluminum, etc.

Referring to FIG. 11, the molding member 118 may be formed on the semiconductor chip 100 and the package substrate 110 to fill up the window 102. Here, the molding member 118 may protect the connecting member 116, the semiconductor chip 100 and the package substrate 110 from external environments such as impacts.

In this example embodiment, the molding member 118 may have a liquid type or a tape type. For example, the molding member 118 may include a liquid molding material, a molding compound, etc. Particularly, the molding compound may include epoxy, polyimide, polybenzoxazole, benzocyclobutene, etc.

Referring to FIG. 12, outer terminals 120 may be mounted on a lower surface of the package substrate 110 to electrically connect the outer terminals 120 with the semiconductor chip 100 via the package substrate 110.

In this example embodiment, examples of the outer terminals 120 may include a solder ball, a solder bump, a metal bump, etc. The metal bump may include copper, gold, nickel, etc.

According to the present embodiment, the second attaching member in the peripheral region of the package substrate may include the repetitive patterns spaced apart from each other by substantially the same interval. Therefore, a delamination between the molding member and the package substrate may be effectively suppressed. As a result, the semiconductor package including the package substrate and the second attaching member may have improved reliability.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor package comprising:
a semiconductor chip;
a package substrate having a chip region and a peripheral region;
a first attaching member arranged in the chip region to attach the semiconductor chip to the chip region of the package substrate;
a second attaching member arranged in the peripheral region, the second attaching member including first attaching patterns that extend in a first direction and second attaching patterns that extend in a second direction;
a connecting member to electrically connect the semiconductor chip with the package substrate; and
a molding member attached to the package substrate by the second attaching member to mold the semiconductor chip.

2. The semiconductor package of claim 1, wherein the first direction is substantially the same as the second direction.

3. The semiconductor package of claim 1, wherein the first direction is substantially perpendicular to the second direction.

4. The semiconductor package of claim 3, wherein the first attaching patterns and the second attaching patterns are intersected with each other at corners of the package substrate.

5. The semiconductor package of claim 1, wherein the first attaching patterns and the second attaching patterns have a bar shape.

6. The semiconductor package of claim 5, wherein the first attaching patterns and the second attaching patterns are inclined to a side surface of the package substrate.

7. The semiconductor package of claim 1, wherein the first attaching patterns and the second attaching patterns have a wavelike shape.

8. The semiconductor package of claim 1, wherein the first direction and the second direction are substantially the same as arrangement directions of the first attaching patterns and the second attaching patterns.

9. The semiconductor package of claim 1, wherein the first direction and the second direction are substantially perpendicular to as arrangement directions of the first attaching patterns and the second attaching patterns.

10. The semiconductor package of claim 1, further comprising outer terminals electrically connected to the semiconductor chip and the package substrate.

11. A semiconductor package comprising:
a semiconductor chip;
a package substrate having a chip region and a peripheral region;
a first attaching member arranged in the chip region to attach the semi-conductor chip to the chip region of the package substrate;
a second attaching member arranged in the peripheral region, the second attaching member including attaching patterns that are spaced apart from each other by substantially the same interval;
a connecting member to electrically connect the semiconductor chip with the package substrate; and
a molding member attached to the package substrate by the second attaching member to mold the semiconductor chip.

12. The semiconductor package of claim 11, wherein:
the attaching patterns of the second attaching member have a bar shape and
an extending direction of the attaching patterns is substantially the same as an arrangement direction of the attaching patterns.

13. The semiconductor package of claim 11, wherein:
the attaching patterns of the second attaching member have a bar shape; and
an extending direction of the attaching patterns is substantially perpendicular to as an arrangement direction of the attaching patterns.

14. A semiconductor package comprising:
a package substrate;
a semiconductor disposed on the package substrate;
a molding formed on the package and the semiconductor; and
an attaching member disposed between the package substrate and the molding, and having at least two different patterns.

15. The semiconductor package of claim 14, wherein the at least two different patterns of the attaching member are disposed on at least two different portions between the package substrate and the molding.

16. The semiconductor package of claim 14, wherein the at least two different patterns of the attaching member are disposed on at least two different portions between the semiconductor and outer peripheral sides of the package substrate.

17. The semiconductor package of claim 14, wherein the at least two different patterns of the attaching member comprise a plurality of bars having corresponding spaces therebetween by a distance.

18. The semiconductor package of claim 14, wherein each of the at least two different patterns of the attaching member comprise one or more bar-shape elements spaced apart frog each other to be parallel to a direction of a side of the semiconductor chip.

19. The semiconductor package of claim 14, wherein the length is longer than the thickness and the height.
